(19) United States
(12) Patent Application Publication
(10) Pub. No.: US 2012/0148055 A1
(43) Pub. Date: Jun. 14, 2012

(54) AUDIO PROCESSING APPARATUS, AUDIO RECEIVER AND METHOD FOR PROVIDING AUDIO THEREOF

(75) Inventors: Tae-hyung LEE, Seoul (KR); Chang-yong HEO, Seoul (KR)

(73) Assignee: SAMSUNG ELECTRONICS CO., LTD., Suwon-si (KR)

(21) Appl. No.: 13/110,222

(22) Filed: May 18, 2011

(30) Foreign Application Priority Data
Dec. 13, 2010 (KR) 2010-0127067

(51) Int. Cl. H04R 29/00; H03G 3/00

(52) U.S. Cl. 381/56; 381/61

(57) ABSTRACT

Provided are an audio processing apparatus and a method for providing audio thereof, and an audio receiver and a method of providing audio thereof. The audio processing apparatus includes: a location detecting unit which detects a location of an audio receiver; a sound adjusting unit which adjusts a sound of an audio signal according to the detected location; and an audio signal transmitting unit which transmits the audio signal with the adjusted sound to the audio receiver.

### CROSS-REFERENCE TO RELATED APPLICATION

This application claims priority from Korean Patent Application No. 10-2010-0127067, filed on Dec. 13, 2010 in the Korean Intellectual Property Office, the disclosure of which is incorporated herein by reference in its entirety.

### BACKGROUND

1. Field

Apparatuses and methods consistent with exemplary embodiments relate to an audio processing apparatus, an audio receiver, and a method for providing audio thereof, and more particularly, to an audio processing apparatus, an audio receiver, and a method for providing audio thereof which provide an audio signal by reflecting an audio effect according to location of the audio receiver.

2. Description of the Related Art

Audio processing apparatuses have been developed to support a sound listening function by use of wireless earphones which utilize various wireless technologies. There are also three dimensional (3D) glasses for 3D TVs equipped with wireless earphones.

However, the related art audio processing apparatuses wirelessly transmit the same sound as the sound delivered to a speaker without considering locations of the listeners. To be specific, the audio processing apparatus always outputs same sound to a wireless earphone without considering the location of the listener. Accordingly, since the wireless earphone also plays back the sound as received, the listener has no choice but to listen to the sound irrespective of a location thereof.

There are cases where a plurality of users listen to sound using different wireless earphones and the users want to be provided with different sound effects. However, the related audio processing apparatus cannot provide various sounds to suit different demands of the users, since the related audio processing apparatus is capable of controlling only one audio output.

### SUMMARY

Exemplary embodiments overcome the above disadvantages and other disadvantages not described above. Also, an exemplary embodiment is not required to overcome the disadvantages described above, and an exemplary embodiment may not overcome any of the problems described above.

According to aspects of one or more exemplary embodiments, an audio processing apparatus, an audio receiver and a method for providing audio thereof are provided, which are capable of providing an audio signal by reflecting a audio effect according to a location of the audio receiver.

According to an aspect of an exemplary embodiment, there is provided an audio processing apparatus providing an audio signal to an audio receiver, the audio processing apparatus including: a location detecting unit which detects a location of the audio receiver; a sound adjusting unit which adjusts a sound of the audio signal according to the detected location; and an audio signal transmitting unit which transmits the audio signal with the adjusted sound to the audio receiver.

The location detecting unit may detect at least one of a distance between the audio receiver and the audio processing apparatus, and a direction of the audio receiver.

The sound adjusting unit may at least one of adjust an output of the audio signal according to the detected distance, and adjust a left-right balance of the audio signal according to the detected direction.

The audio processing apparatus may be connected to a plurality of audio receivers, the location detecting unit may detect locations of the plurality of audio receivers, the sound adjusting unit may generate a plurality of audio signals with sounds adjusted according to the plurality of detected audio receivers, and the audio signal transmitting unit may transmit the generated plurality of audio signals with the adjusted sounds to the plurality of audio receivers.

The audio processing apparatus may additionally include a multiplexer (MUX) which multiplexes the generated plurality of audio signals with the adjusted sounds into one signal, and the audio signal transmitting unit may transmit the multiplexed audio signal to the plurality of audio receivers.

The location detecting unit may detect unique identification codes corresponding to the plurality of audio receivers, and the MUX may multiplex the generated plurality of audio signals with the adjusted sounds and the unique identification codes corresponding to the generated plurality of audio signals into the one signal.

The audio receiver may include at least one of a wireless earphone, a wireless headphone, three dimensional (3D) glasses, and a remote controller.

According to an aspect of another exemplary embodiment, there is provided an audio receiver receiving an audio signal from an audio processing apparatus, the audio receiver including: a location information transmitting unit which transmits location information of the audio receiver to the audio processing apparatus; an audio receiving unit which receives a signal containing an audio signal corresponding to the transmitted location information; a de-multiplexer (de-MUX) which de-multiplexes the audio signal of the received signal which corresponds to the transmitted location information; and an audio output unit which outputs the de-multiplexed audio signal.

The location information may include a unique identification code of the audio receiver, and the de-MUX may demultiplex the audio signal which corresponds to the unique identification code.

According to an aspect of another exemplary embodiment, there is provided an audio receiver receiving an audio signal from an audio processing apparatus, the audio receiver including: a location detecting unit which detects a location of the audio processing apparatus; an audio receiving unit which receives the audio signal from the audio processing apparatus; a sound adjusting unit which adjusts a sound of the received audio signal according to the detected location of the audio processing apparatus; and an audio output unit which outputs the audio signal with the adjusted sound.

The location detecting unit may detect at least one of a distance between the audio receiver and the audio processing apparatus, and a direction of the audio processing apparatus.

The sound adjusting unit may at least one of adjust an output of the received audio signal according to the detected distance, and adjust a left-right balance of the received audio signal according to the detected direction.

According to an aspect of another exemplary embodiment, there is provided a method for providing audio at an audio processing apparatus which provides an audio signal to an audio receiver, the method including: detecting a location of the audio receiver; adjusting a sound of the audio signal according to the detected location; and transmitting the audio signal with the adjusted sound to the audio receiver.

The detecting may include detecting at least one of a distance between the audio receiver and the audio processing apparatus, and a direction of the audio receiver.

The adjusting may include at least one of adjusting an output of the audio signal according to the detected distance, and adjusting a left-right balance of the audio signal according to the detected direction.

The audio processing apparatus may be connected to a plurality of audio receivers, the detecting may include detecting locations of the plurality of audio receivers, the adjusting may include generating a plurality of audio signals with sounds adjusted according to the plurality of detected audio receivers, and the transmitting may include transmitting the generated plurality of audio signals with the adjusted sounds to the plurality of audio receivers.

The method may additionally include multiplexing the generated plurality of audio signals with the adjusted sounds into one signal, and the transmitting may include transmitting the multiplexed audio signal to the plurality of audio receivers.

The detecting may include detecting unique identification codes corresponding to the plurality of audio receivers, and the multiplexing may include multiplexing the generated plurality of audio signals with the adjusted sounds and the unique identification codes corresponding to the generated plurality of audio signals into one signal.

According to an aspect of another exemplary embodiment, there is provided a method for providing audio at an audio receiver which receives an audio signal from an audio processing apparatus, the method including: transmitting location information of the audio receiver to the audio processing apparatus; receiving a signal containing the audio signal corresponding to the transmitted location information; de-multiplexing the audio signal of the received signal which corresponds to the transmitted location information; and outputting the de-multiplexed audio signal.

The location information may include at least one of a unique identification code of the audio receiver, and the multiplexing may include demultiplexing the audio signal which corresponds to the unique identification code.

According to an aspect of another exemplary embodiment, there is provided a method for providing audio at an audio receiver which receives an audio signal from an audio processing apparatus, the method including: detecting a location of the audio processing apparatus; receiving the audio signal from the audio processing apparatus; adjusting a sound of the received audio signal according to the detected location of the audio processing apparatus; and outputting the audio signal with the adjusted sound.

The detecting may include detecting at least one of a distance between the audio receiver and the audio processing apparatus, and a direction of the audio processing apparatus.

The adjusting may include at least one of adjusting an output of the audio signal according to the detected distance, and adjusting a left-right balance of the audio signal according to the detected direction.

According to an aspect of another exemplary embodiment, there is provided a method for providing audio at an audio processing apparatus which provides an audio signal to an audio receiver, the method including: transmitting, to the audio receiver, location information of the audio processing apparatus; transmitting, to the audio receiver, the audio signal, wherein the location information is used by the audio receiver to adjust a sound of the audio signal.

### BRIEF DESCRIPTION OF THE DRAWINGS

The above and/or other aspects will be more apparent by describing certain exemplary embodiments with reference to the accompanying drawings, in which:

FIG. 1 is a block diagram of an audio processing system according to an exemplary embodiment;

FIG. 2 is a detailed block diagram of an audio processing apparatus according to an exemplary embodiment;

FIG. 3 is a detailed block diagram of the audio processing unit of FIG. 2;

FIG. 4 is a detailed block diagram of an audio receiver according to an exemplary embodiment;

FIG. 5 is a detailed block diagram of an audio processing apparatus according to another exemplary embodiment;

FIG. 6 is a detailed block diagram of an audio receiver according to another exemplary embodiment;

FIG. 7 is a flowchart provided to explain a method for providing audio at an audio processing apparatus according to an exemplary embodiment;

FIG. 8 is a flowchart provided to explain a method for providing audio at an audio receiver according to an exemplary embodiment; and

FIG. 9 is a flowchart provided to explain a method for providing audio at an audio receiver according to another exemplary embodiment.

### DETAILED DESCRIPTION OF EXEMPLARY EMBODIMENTS

Certain exemplary embodiments will now be described in greater detail with reference to the accompanying drawings.

In the following description, same drawing reference numerals are used for the same elements even in different drawings. The matters defined in the description, such as detailed constructions and elements, are provided to assist in a comprehensive understanding of exemplary embodiments. Accordingly, it is apparent that exemplary embodiments can be carried out without those specifically defined matters. Also, well-known functions or constructions are not described in detail since they would obscure the description with unnecessary detail. Furthermore, expressions such as “at least one of,” when preceding a list of elements, modify the entire list of elements and do not modify the individual elements of the list.

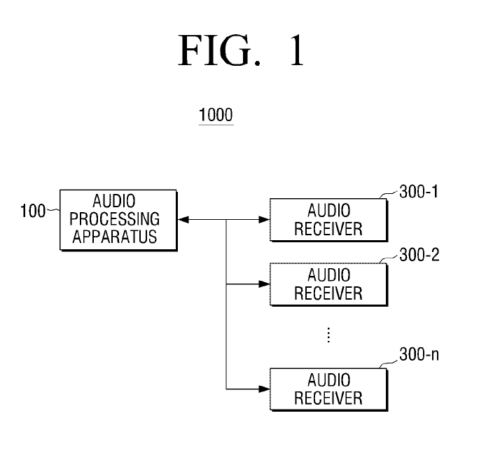

FIG. 1 is a block diagram of an audio processing system 1000 according to an exemplary embodiment.

Referring to FIG. 1, an audio processing system 1000 may include an audio processing apparatus 100 and a plurality of audio receivers 300.

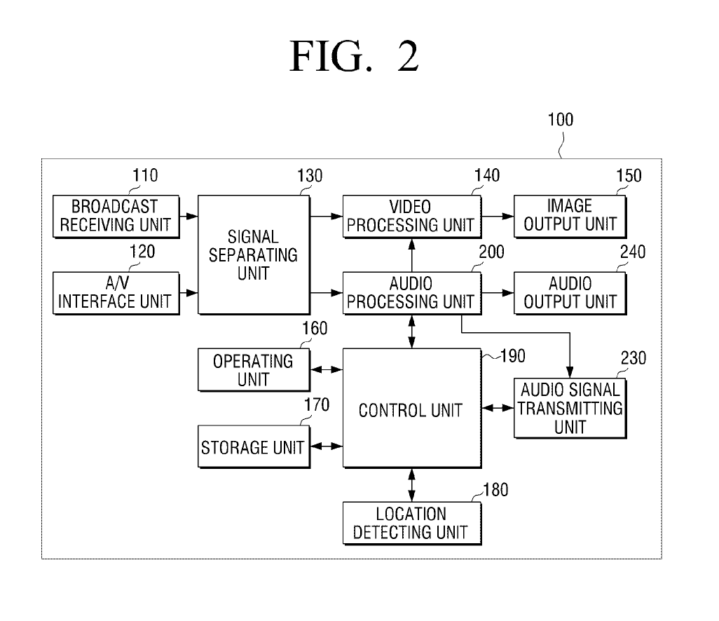

The audio processing apparatus 100 detects locations of the audio receivers 300, adjusts sound of an audio signal according to the detected locations, and provides the audio signal with the adjusted sound to the audio receivers 300. For example, the audio processing apparatus 100 and may be implemented as a digital TV, a Set-top box, a personal computer (PC), a laptop computer, a portable multimedia player (PMP), etc. A detailed construction and operation of the audio processing apparatus 100 will be explained below with reference to FIG. 2.

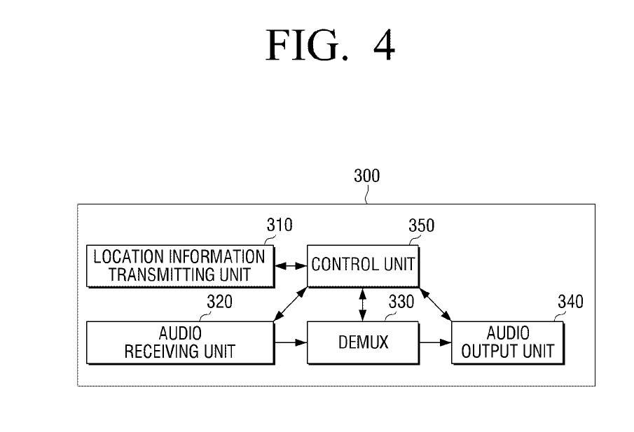

The audio receivers 300 receive audio signals from the audio processing apparatus 100 and provide the users with the received audio signals. For example, the audio receivers 300 may be implemented as wireless earphones, wireless headphones, 3D glasses, remote controllers, etc. A detailed construction and operation of the audio receivers 300 will be explained below with reference to FIG. 4.

FIG. 2 is a detailed block diagram of the audio processing apparatus 100 according to an exemplary embodiment.

Referring to FIG. 2, the audio processing apparatus 100 may include a broadcast receiving unit 110, an A/V interface unit 120, a signal separating unit 130, a video processing unit 140, an image output unit 150, an operating unit 160, a storage unit 170, a location detecting unit 180, a control unit 190, an audio processing unit 200, an audio signal transmitting unit 230, and an audio output unit 240.

The broadcast receiving unit 110 receives a broadcast from a broadcasting station or a satellite by in a wired or a wireless manner, and demodulates the received broadcast. Further, the broadcast receiving unit 110 may receive a two dimensional image signal, or a three dimensional video image signal containing three dimensional image data.

The A/V interface unit 120 is connected to an external device and receives an image therefrom. The A/V interface unit 120 may particularly receive 2D image data or 3D image data from the external device. An example of the A/V interface unit 120 includes interfaces using S-Video, component, composite, D-Sub, DVI, HDMI, etc.

The ‘3D image data’ herein refers to data that contains 3D image information. The 3D image data contains left-eye image data and right-eye image data in one data frame region. The 3D image data is also categorized into different types depending on the manner the 3D image data contains the left-eye image data and the right-eye image data. For example, the 3D image data may be classified into an interleave type, a side-by-side type, a top-bottom type, etc.

The signal separating unit 130 separates the received image signal into an audio signal and a video signal. The signal separating unit 130 also outputs the audio signal to the audio processing unit 200 and the video signal to the video processing unit 140.

The video processing unit 140 handles signal processing such as at least one of video decoding, video scaling, etc., with respect to the video signal inputted from the signal separating unit 130. The video processing unit 140 then outputs the processed video signal to the image output unit 150.

The ‘video image’ herein refers to content image inputted from outside via the broadcast receiving unit 110 or the A/V interface unit 120. For example, the video image may be a broadcast image or a DVD image. Further, the video image may be 3D image, in which case one video image frame of the video image may includes a left-eye video frame and a right-eye video frame. Accordingly, if the 3D image is inputted, the video processing unit 140 outputs left- and right-eye video images.

The image output unit 150 outputs the image processed by the video processing unit 140. In particular, if the 3D image is processed by the video processing unit 140, the image output unit 150 alternately outputs the left- and right-eye images.

The audio processing unit 200 handles signal processing such as audio decoding or the like with respect to the audio signal inputted from the signal separating unit 130. To be specific, the audio processing unit 200 may adjust the sound of the inputted audio signal depending on the location of the audio receiver as detected by the location detecting unit 180, which will be explained in detail below.

To be specific, the audio processing unit 200 may adjust the audio signal output depending on a distance detected through the location detecting unit 180. For example, if the location of the audio receiver is detected to be farther than a preset location or distance, the output of the audio signal is decreased, and if the location of the audio receiver is detected to be closer than the preset location or distance, the output of the audio signal is increased. The audio processing unit 200 may also adjust a left-right balance of the audio signal according to the direction of the audio receivers detected through the location detecting unit 180. For example, if the audio receiver is closer to the left side, the audio processing unit 300 increases a left-side balance, and if the audio receiver is closer to the right side, the audio processing unit 300 increases a right-side balance of the audio signal.

Further, the audio processing unit 200 may provide various other audio effects such as surround sound according to the detected locations of the audio receivers. The audio processing unit 200 outputs the processed audio signal to the audio output unit 240 or the audio signal transmitting unit 230.

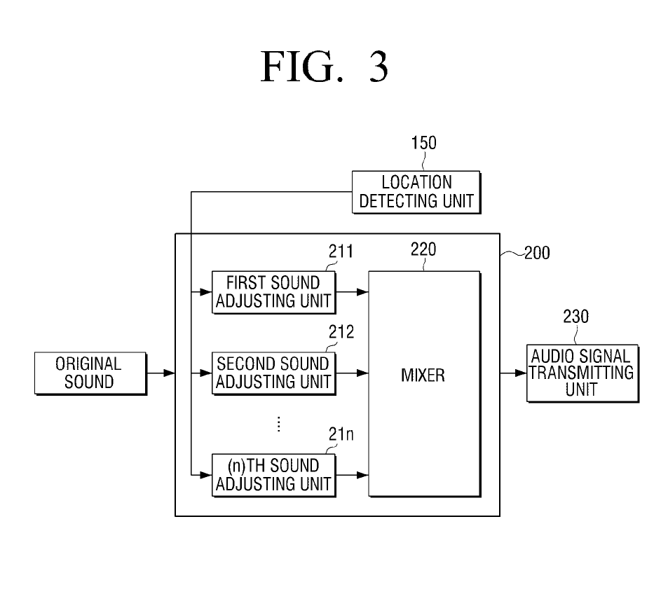

Meanwhile, the audio processing apparatus 100 may be connected to a plurality of audio receivers, in which case the audio processing unit 200 may adjust the sound of the audio signal separated at the signal separating unit 130 according to the audio receivers, respectively. This will be explained in greater detail below with reference to FIG. 3.

The audio signal transmitting unit 230 transmits the audio signal with the adjusted sound to the audio receivers. To be specific, the audio signal transmitting unit 230 may transmit the audio signal with the sound adjusted at the audio processing unit 200 to the audio receivers.

The audio output unit 240 outputs the audio signal processed at the audio processing unit 200 via internal speaker. Further, the audio output unit 240 may output the processed audio signal via an external speaker connected thereto. Meanwhile, the audio output unit 240 may not operate when the audio signal is transmitted via the audio signal transmitting unit 230.

The operating unit 160 receives a command according to a user's manipulation. The operating unit 160 may be implemented in the form of at least one of buttons on the surface of the audio processing unit 100, a touch screen on the image output unit 150, etc. Meanwhile, the operating unit 160 may be implemented as a remote controller.

The storage unit 170 records and thus stores therein the image received at the broadcast receiving unit 110 or the A/V interface unit 120. Further, the storage unit 170 stores various types of content files. The storage unit 170 may be implemented in the form of a hard disk drive, non-volatile memory, or the like.

The location detecting unit 180 detects the locations of the audio receivers. To be specific, the location detecting unit 180 detects distances between the audio receivers and the audio processing apparatus 100 using, for example, a plurality of ultrasound sensors or infrared sensors, and detects the directions of the audio receivers based on the difference in the detected results at two sensors. Meanwhile, if a plurality of audio receivers 300 is connected to the audio processing apparatus 100, the location detecting unit 180 may detect the respective locations of the plurality of audio receivers. The location detecting unit 180 may discern the plurality of audio receivers from each other by receiving the location information containing unique identification codes from the respective audio receivers 300.

The control unit 190 analyzes the user's command based on the user's manipulation transmitted from the operating unit 160, and controls the overall operation of the audio processing apparatus 100 according to the analyzed user's command.

To be specific, the control unit 190 may control the broadcast receiving unit 110, the A/V interface unit 120, the signal separating unit 130, the video processing unit 140, the image output unit 150, the storage unit 170, the location detecting unit 180, the audio processing unit 200, the audio signal transmitting unit 230, and the audio output unit 240 to perform the above-explained operations, respectively.

A detailed construction of the audio processing unit 200 will be explained in greater detail below, with reference to FIG. 3.

FIG. 3 is a detailed block diagram of the audio processing unit 200 of FIG. 2.

Referring to FIG. 3, the audio processing unit 200 may include a plurality of sound adjusting units 211, 212, . . . 21n, and a mixer 220.

The sound adjusting unit 210 generates a plurality of audio signals of which sound is adjusted according to the plurality of detected audio receivers. To be specific, the sound adjusting unit 210 may receive a plurality of location information detected through the location detecting unit 180 and generate a plurality of audio signals of which sound is adjusted according to the received location information.

The mixer 220 multiplexes the plurality of sound-adjusted audio signals into one signal. To be specific, the mixer 220 may multiplex the plurality of audio signals with adjusted sound generated at the plurality of sound adjusting units 210 into one signal.

The mixer 220 may multiplex the plurality of audio signals and the unique identification codes corresponding to the plurality of audio signals into one signal. To be specific, the mixer 220 may multiplex the unique identification codes for use at the audio receivers 300 to de-multiplex the audio signals, along with the plurality of audio signals of adjusted sounds.

The audio signal transmitting unit 230 transmits the multiplexed audio signals to the plurality of audio receivers 300. To be specific, the audio signal transmitting unit 230 may transmit the signal multiplexed at the mixer 220 to the plurality of audio receivers 300 using one channel.

As explained above, since the audio processing apparatus 100 according to an exemplary embodiment adjusts sound of an audio signal according to a detected location of the audio receiver and provides the audio signal with the adjusted sound, the audio processing apparatus 100 is capable of providing various sounds according to respective locations of the users. Further, since different adjustments are applied to the sounds of the respective audio receivers, the plurality of users can receive individual sound effects.

Although the plurality of sound adjusting units 210 has been implemented in the exemplary explained above to generate a plurality of audio signals with a plurality of adjusted sounds, it is understood that another exemplary embodiment is not limited thereto. For example, according to another exemplary embodiment, one sound adjusting unit 210 may be used to generate a plurality of audio signals with adjusted sounds.

Furthermore, although the plurality of generated audio signals with adjusted sounds is multiplexed into one signal and transmitted as such in the exemplary embodiment explained above, it is understood that another exemplary embodiment is not limited thereto. For example, in another embodiment, the audio signals with adjusted sounds can be transmitted over different channels.

FIG. 4 is a detailed block diagram of an audio receiver 300 according to an exemplary embodiment.

Referring to FIG. 4, the audio receiver 300 according to an exemplary embodiment may include a location information transmitting unit 310, an audio receiving unit 320, a de-mux 330, an audio output unit 340, and a control unit 350.

The location information transmitting unit 310 transmits location information of the audio receiver 300 to the audio processing apparatus 100. To be specific, the location information transmitting unit 310 may transmit a signal containing a unique identification code of the audio receiver with an ultrasound signal or an infrared signal.

The audio receiving unit 320 may receive an audio signal from the audio processing apparatus 100. To be specific, the audio receiving unit 320 may receive one signal into which a plurality of audio signals is multiplexed, or may receive a signal containing one audio signal transmitted over a devoted channel.

The de-mux 330 de-multiplexes the audio signal, of the plurality of audio signals multiplexed into the received signal, that corresponds to the received location information. To be specific, from among the plurality of audio signals of the received signal, the de-mux 330 may de-multiplex an audio signal that corresponds to its own location using its unique identification code.

The audio output unit 340 may handle signal processing with respect to the audio signal de-multiplexed at the de-mux 330. To be specific, if the audio signal de-multiplexed by the de-mux 330 is a digital signal, the audio output unit 340 may convert the de-multiplexed digital signal into an analog signal, and may amplify the analog signal into a signal audible by the listener.

Additionally, the audio output unit 340 outputs the signal-processed audio signal via an internal speaker (e.g., an earphone). Further, the audio output unit 340 may output the audio-processed audio signal via an externally-connected speaker.

The control unit 350 controls the respective components within the audio receiver 300. To be specific, at predetermined intervals, or upon changing of location of the audio receiver, the control unit 350 may control the location information transmitting unit 310 to transmit the location information for detection of location of the audio receiver 300 to the audio processing apparatus 100, and when a signal containing an audio signal corresponding to the transmitted location information is received via the audio receiving unit 320, the control unit 350 may control the de-mux 330 to de-multiplex the audio signal that corresponds to its own unique identification information, and also control the audio output unit 340 to reproduce the de-multiplexed audio signal.

Accordingly, since the audio receiver 300 according to an exemplary embodiment provides the audio processing apparatus 100 with its own location and receives an audio signal with the sound adjusted according to its location from the audio processing apparatus 100, user convenience can improve.

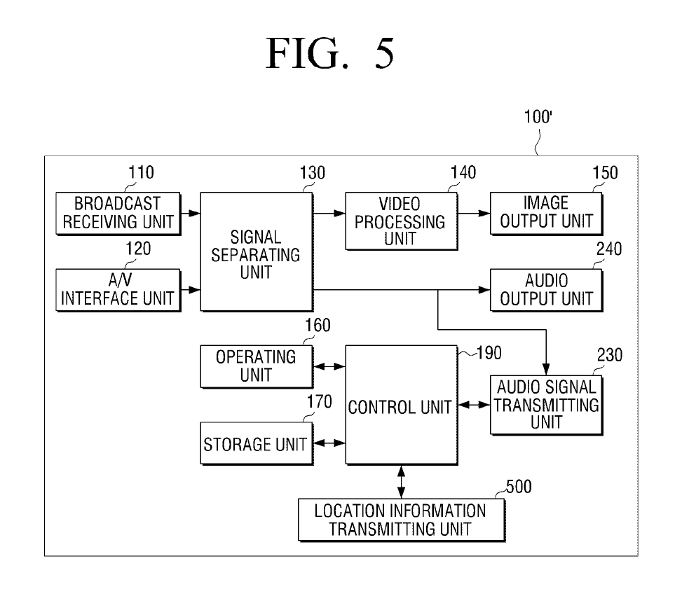

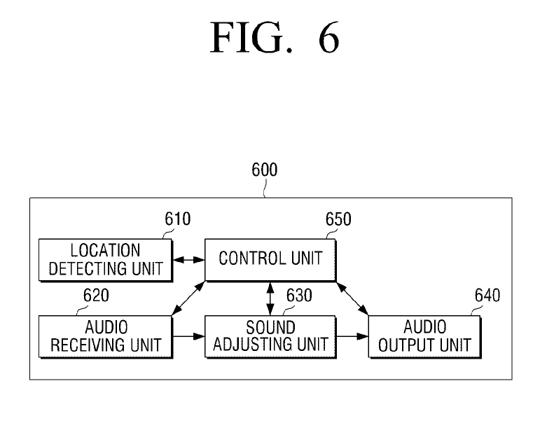

In the exemplary embodiment explained above with reference to FIGS. 2 and 3, it has been explained that the audio processing apparatus 100 detects the location of the audio receiver 300 and adjusts the sound of the audio signal according to the detected location. However, it is understood that another exemplary embodiment is not limited thereto. For example, according to another exemplary embodiment, the audio receiver 300 may directly detect its own location and directly adjust the sound of the audio signal according to the detected location. This will be explained in greater detail below with reference to FIGS. 5 and 6.

FIG. 5 is a detailed block diagram of an audio processing apparatus 100′ according to another exemplary embodiment.

Referring to FIG. 5, the audio processing apparatus 100′ may include a broadcast receiving unit 110, an A/V interface unit 120, a signal separating unit 130, a video processing unit 140, an image output unit 150, an operating unit 160, a storage unit 170, a location information transmitting unit 500, a control unit 190, an audio signal transmitting unit 230, and an audio output unit 240.

Compared to the audio processing apparatus 100 illustrated in FIG. 2, the audio processing apparatus 100′ of FIG. 5 does not have the audio processing unit 200, and additionally includes the location information transmitting unit 500 instead of the location detecting unit 180.

The signal separating unit 130, the video processing unit 140, the image output unit 150, the operating unit 160, the storage unit 170, the control unit 190, the audio signal transmitting unit 230 and the audio output unit 240 are similar or identical to those illustrated in FIG. 2 and thus will not be explained in detail below.

The location information transmitting unit 500 transmits location information of the audio processing apparatus 100′ to the audio receiver 600. To be specific, the location information transmitting unit 310 may transmit an ultrasound signal or an infrared signal to notify the location of the audio processing apparatus 100′ at predetermined intervals or upon receipt of a request from an audio receiver 600.

The audio processing apparatus 100′ according to an exemplary embodiment may carry out sound processing with respect to the audio signal separated at the signal separating unit 130 before transmitting the same, and in this case, a separate device having only the location information transmitting unit 500 may be attached to a related art audio processing apparatus to implement the audio processing apparatus 100′ according to the present exemplary embodiment.

FIG. 6 is a detailed block diagram of an audio receiver 600 according to another exemplary embodiment.

Referring to FIG. 6, the audio receiver 600 according to an exemplary embodiment may include a location detecting unit 610, an audio receiving unit 620, a sound adjusting unit 630, an audio output unit 640, and a control unit 650.

The location detecting unit 610 detects the location of the audio receiver 600. To be specific, the location detecting unit 610 detects a distance between the audio receiver 600 and the audio processing apparatus 100′ using a plurality of ultrasound sensors or infrared sensors, and detects the direction of the audio receiver 600 based on a difference in detection results at two sensors.

The audio receiving unit 620 may receive the audio signal from the audio processing apparatus 100.

The sound adjusting unit 630 carries out signal processing such as audio decoding or the like with respect to the audio signal received by the audio receiving unit 620.

The sound adjusting unit 630 may also adjust the sound of the inputted audio signal according to the location of the audio receiver 600 detected by the location detecting unit 610. To be specific, the sound adjusting unit 630 may adjust the output of the audio signal according to the distance detected by the location detecting unit 610. For example, if the detected location is farther than a preset distance or location, the output of the audio signal is decreased, and if the detected location is closer than the preset location or distance, the output of the audio signal is increased.

The sound adjusting unit 630 may additionally adjust a left-right balance of the audio signal according to the direction of the audio receiver 600 detected by the location detecting unit 610. For example, if the audio receiver 600 is closer to the left side, the audio processing unit 630 may increase a left-side balance of the audio signal, and if the audio receiver 600 is closer to the right side, the audio processing unit 630 may increase a right-side balance of the audio signal.

Further, the sound adjusting unit 630 may add various other audio effects such as surround sound, depending on the detected location thereof.

The audio output unit 640 converts the audio signal with sound adjusted at the sound adjusting unit 630 into an analog signal, and outputs the converted audio signal via the internal speaker (e.g., an earphone). Further, the audio output unit 640 may output the converted audio signal via an externally-connected speaker.

The control unit 650 controls the respective components within the audio receiver 600. To be specific, the control unit 650 may control the location detecting unit 610 to detect the location thereof according to the location information transmitted from the audio processing apparatus 100′, control the sound adjusting unit 630 to carry out sound adjustment with respect to the received audio signal according to the detected location, and control the audio output unit 640 to reproduce the audio signal with the adjusted sound.

Although it has been explained that the audio receiver 600 detects the location thereof according to the location information received from the audio processing apparatus 100′ in the above exemplary embodiment, it is understood that another exemplary embodiment is not limited thereto. For example, in another embodiment, the audio receiver 600 may detect the location thereof based on the user's manipulation or the like, without receiving separate information from the audio processing apparatus 100′.

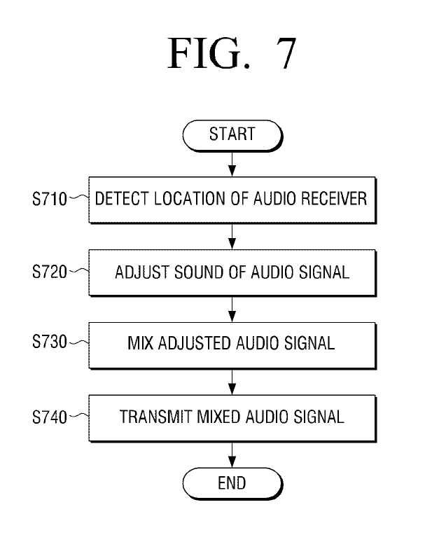

FIG. 7 is a flowchart provided to explain a method for providing audio by an audio processing apparatus according to an exemplary embodiment.

At operation S710, the location of the audio receiver is detected. To be specific, a distance between the audio receiver and the audio processing apparatus is detected using a plurality of ultrasound sensors or infrared sensors, and a direction of the audio receiver is detected based on the difference in the detected results of two sensors.

At operation S720, the sound of the audio signal is adjusted according to the detected location. To be specific, the output of the audio signal is adjusted according to the detected distance to the audio receiver, and the left-right balance of the audio signal may be adjusted according to the detected direction of the audio receiver.

At operation S730, a plurality of audio signals with adjusted sounds is multiplexed. To be specific, if the audio processing apparatus is in the process of providing the audio signal to the plurality of audio receivers, the audio signals with sounds adjusted with respect to the respective audio receivers and unique identification codes corresponding to the audio receivers may be multiplexed into one signal.

At operation S740, the multiplexed audio signal is transmitted. To be specific, the multiplexed signal may be transmitted generally to the plurality of audio receivers over one channel. In another exemplary embodiment, the signal may be transmitted discriminately using channels individually allotted to the audio receivers, respectively.

With the method for providing audio at the audio processing apparatus according to the present exemplary embodiment, since the sound of the audio signal is adjusted according to the detected locations of the audio receivers, various sounds can be provided to the users at difference locations. Further, since different sound adjustments are applied to each of the users, various sound effects can be provided.

The method for providing audio as illustrated in FIG. 7 may be implemented in the audio processing apparatus 100 constructed as illustrated in FIG. 2, or in other audio processing apparatuses with different constructions.

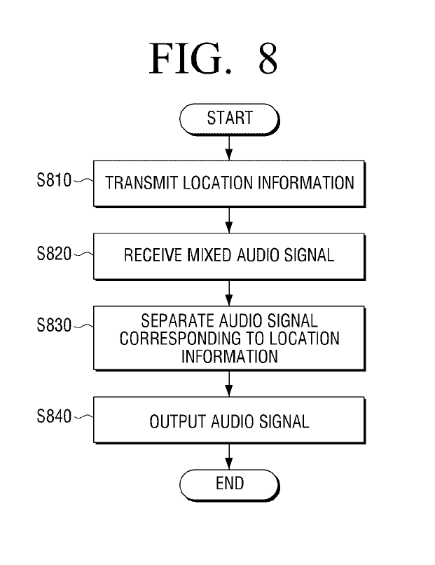

FIG. 8 is a flowchart provided to explain a method for providing audio at an audio receiver according to an exemplary embodiment.

At operation S810, location information of the audio receiver 300 is transmitted to the audio processing apparatus 100. To be specific, a signal containing a unique identification code of the audio receiver 300 may be transmitted in the from of an ultrasound signal or infrared signal.

At operation S820, a signal containing the audio signal corresponding to the transmitted location information is received. To be specific, one signal into which a plurality of audio signals is multiplexed may be received, or a signal containing only one audio signal transmitted over a devoted channel may be received.

At operation S830, an audio signal of the received signal which corresponds to the transmitted signal (i.e., location information) is de-multiplexed. To be specific, in the audio signal containing a plurality of audio signals, the audio signal that matches the unique identification code of the audio receiver may be de-multiplexed.

At operation S840, the de-multiplexed audio signal is outputted. To be specific, the de-multiplexed audio signal may be converted into an audio signal audible to the user, and the converted signal may be output via an internal speaker or an external speaker.

Accordingly, the method for providing audio at the audio receiver according to the present exemplary embodiment provides improved user convenience, since the location of the audio receiver is provided to the audio processing apparatus, and the audio signal with the sound adjusted according to the location of the audio receiver is received from the audio processing apparatus and provided to the user. The method for providing audio as illustrated in FIG. 8 may be implemented in the audio receiver 300 constructed as illustrated in FIG. 4, or in other audio receivers with different constructions.

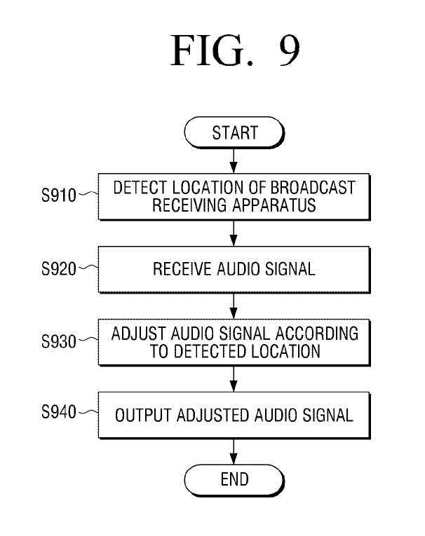

FIG. 9 is a flowchart provided to explain a method for providing audio at an audio receiver according to another exemplary embodiment.

At operation S910, the location of the audio processing apparatus 100′ is detected. To be specific, a distance between the audio receiver and the audio processing apparatus is detected using a plurality of ultrasound sensors or infrared sensors, and a direction of the audio receiver is detected based on the difference in the detected results of the two sensors.

At operation S920, an audio signal is received from the audio processing apparatus.

At operation S930, sound of the received audio signal is adjusted according to the detected location. To be specific, at least one of the output of the audio signal may be adjusted according to the detected distance, and a left-right balance of the audio signal may be adjusted according to the detected direction.

At operation S940, the audio signal with adjusted sound is output. To be specific, the audio signal with the adjusted sound is converted into an audio signal audible by the user, and the converted signal may be output via an internal speaker or an external speaker.

Accordingly, the method for providing audio at the audio receiver according to the present exemplary embodiment provides improved user convenience, since the location of the audio receiver is detected, and the sound of the received audio signal is adjusted according to the detected location and provided to the user. The method for providing audio as illustrated in FIG. 9 may be implemented in the audio receiver 600 constructed as illustrated in FIG. 6, or in other audio receivers with different constructions.

While not restricted thereto, exemplary embodiments can also be embodied as computer-readable code on a computer-readable recording medium. The computer-readable recording medium is any data storage device that can store data that can be thereafter read by a computer system. Examples of the computer-readable recording medium include read-only memory (ROM), random-access memory (RAM), CD-ROMs, magnetic tapes, floppy disks, and optical data storage devices. The computer-readable recording medium can also be distributed over network-coupled computer systems so that the computer-readable code is stored and executed in a distributed fashion. Also, exemplary embodiments may be written as computer programs transmitted over a computer-readable transmission medium, such as a carrier wave, and received and implemented in general-use or special-purpose digital computers that execute the programs. Moreover, one or more units of the audio processing apparatus 100 or 100′ and the audio receiver 300 or 600′ can include a processor or microprocessor executing a computer program stored in a computer-readable medium.

The foregoing exemplary embodiments and advantages are merely exemplary and are not to be construed as limiting the present inventive concept. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. An audio processing apparatus providing an audio signal to an audio receiver, the audio processing apparatus comprising:
a location detecting unit which detects a location of the audio receiver;
a sound adjusting unit which adjusts a sound of the audio signal according to the detected location; and
an audio signal transmitting unit which transmits the audio signal with the adjusted sound to the audio receiver.

2. The audio processing apparatus of claim 1, wherein the location detecting unit detects at least one of a distance between the audio receiver and the audio processing apparatus, and a direction of the audio receiver.

3. The audio processing apparatus of claim 2, wherein the sound adjusting unit adjusts an output of the audio signal according to the detected distance, and adjusts a left-right balance of the audio signal according to the detected direction.

4. The audio processing apparatus of claim 1, wherein:
the audio processing apparatus is connected to a plurality of audio receivers;
the location detecting unit detects locations of the plurality of audio receivers;
the sound adjusting unit generates a plurality of audio signals, from the audio signal, with sounds adjusted according to the detected locations of the plurality of audio receivers; and
the audio signal transmitting unit transmits the generated plurality of audio signals with the adjusted sounds to the plurality of audio receivers.

5. The audio processing apparatus of claim 4, further comprising:
a multiplexer (MUX) which multiplexes the generated plurality of audio signals with the adjusted sounds into one signal,
wherein the audio signal transmitting unit transmits the multiplexed audio signal to the plurality of audio receivers.

6. The audio processing apparatus of claim 5, wherein:
the location detecting unit detects unique identification codes corresponding to the plurality of audio receivers; and
the MUX multiplexes the generated plurality of audio signals with the adjusted sounds and the detected unique identification codes corresponding to the generated plurality of audio signals into the one signal.

7. The audio processing apparatus of claim 1, wherein the audio receiver comprises at least one of a wireless earphone, a wireless headphone, three-dimensional (3D) glasses, and a remote controller.

8. The audio processing apparatus of claim 4, wherein the audio signal transmitting unit transmits the generated plurality of audio signals with the adjusted sounds to the plurality of audio receivers via a plurality of channels.

9. The audio processing apparatus of claim 1, wherein the location detecting unit detects the location of the audio receiver using location information transmitted from the audio receiver.

10. An audio receiver receiving an audio signal from an audio processing apparatus, the audio receiver comprising:
a location information transmitting unit which transmits location information of the audio receiver to the audio processing apparatus;
an audio receiving unit which receives a signal comprising an audio signal corresponding to the transmitted location information; and
an audio output unit which outputs the audio signal corresponding to the transmitted location information.

11. The audio receiver of claim 8, further comprising:
a de-multiplexer (de-MUX) which de-multiplexes the audio signal of the received signal which corresponds to the transmitted location information,
wherein the audio output unit outputs the de-multiplexed audio signal.

12. The audio receiver of claim 11, wherein the transmitted location information comprises a unique identification code of the audio receiver, and the de-MUX demultiplexes the audio signal which corresponds to the unique identification code.

13. An audio receiver receiving an audio signal from an audio processing apparatus, the audio receiver comprising:
a location detecting unit which detects a location of the audio processing apparatus;
an audio receiving unit which receives the audio signal from the audio processing apparatus;
a sound adjusting unit which adjusts a sound of the received audio signal according to the detected location of the audio processing apparatus; and
an audio output unit which outputs the audio signal with the adjusted sound.

14. The audio receiver of claim 13, wherein the location detecting unit detects at least one of a distance between the audio receiver and the audio processing apparatus, and a direction of the audio processing apparatus.

15. The audio receiver of claim 14, wherein the sound adjusting unit adjusts an output of the received audio signal according to the detected distance, and adjusts a left-right balance of the received audio signal according to the detected direction.

16. A method for providing audio at an audio processing apparatus which provides an audio signal to an audio receiver, the method comprising:
detecting a location of the audio receiver;
adjusting a sound of the audio signal according to the detected location; and
transmitting the audio signal with the adjusted sound to the audio receiver.

17. The method of claim 16, wherein the detecting comprises detecting at least one of a distance between the audio receiver and the audio processing apparatus, and a direction of the audio receiver.

18. The method of claim 17, wherein the adjusting comprises adjusting an output of the audio signal according to the detected distance, and adjusting a left-right balance of the audio signal according to the detected direction.

19. The method of claim 16, wherein:
the audio processing apparatus is connected to a plurality of audio receivers;
the detecting comprises detecting locations of the plurality of audio receivers;
the adjusting comprises generating a plurality of audio signals, from the audio signal, with sounds adjusted according to the detected locations of plurality of audio receivers; and
the transmitting comprises transmitting the generated plurality of audio signals with the adjusted sounds to the plurality of audio receivers.

20. The method of claim 19, further comprising:
multiplexing the generated plurality of audio signals with the adjusted sounds into one signal,
wherein the transmitting the generated plurality of audio signals comprises transmitting the multiplexed audio signal to the plurality of audio receivers.

21. The method of claim 20, wherein:
the detecting further comprises detecting unique identification codes corresponding to the plurality of audio receivers; and
the multiplexing comprises multiplexing the generated plurality of audio signals with the adjusted sounds and the detected unique identification codes corresponding to the generated plurality of audio signals into the one signal.

22. A method for providing audio at an audio receiver which receives an audio signal from an audio processing apparatus, the method comprising:
transmitting location information of the audio receiver to the audio processing apparatus;
receiving a signal comprising an audio signal corresponding to the transmitted location information; and
outputting the audio signal corresponding to the transmitted location information.

23. The method of claim 22, further comprising:
de-multiplexing the audio signal of the received audio signal which corresponds to the transmitted location information,
wherein the outputting comprises outputting the de-multiplexed audio signal.

24. The method of claim 23, wherein:
the location information comprises a unique identification code of the audio receiver; and
the multiplexing comprises demultiplexing the audio signal which corresponds to the unique identification code.

25. A method for providing audio at an audio receiver which receives an audio signal from an audio processing apparatus, the method comprising:
detecting a location of the audio processing apparatus;
receiving the audio signal from the audio processing apparatus;
adjusting a sound of the received audio signal according to the detected location of the audio processing apparatus; and
outputting the audio signal with the adjusted sound.

26. The method of claim 25, wherein the detecting comprises detecting at least one of a distance between the audio receiver and the audio processing apparatus, and a direction of the audio processing apparatus.

27. The method of claim 26, wherein the adjusting comprises adjusting an output of the received audio signal according to the detected distance, and adjusting a left-right balance of the received audio signal according to the detected direction.

28. A method for providing audio at an audio processing apparatus which provides an audio signal to an audio receiver, the method comprising:
transmitting, to the audio receiver, location information of the audio processing apparatus;
transmitting, to the audio receiver, the audio signal,
wherein the location information is used by the audio receiver to adjust a sound of the audio signal.

29. A computer readable recording medium having recorded thereon a program executable by a computer for performing the method of claim 16.

30. A computer readable recording medium having recorded thereon a program executable by a computer for performing the method of claim 22.

31. A computer readable recording medium having recorded thereon a program executable by a computer for performing the method of claim 25.

32. A computer readable recording medium having recorded thereon a program executable by a computer for performing the method of claim 28.
